(19) United States
(12) Patent Application Publication
(10) Pub. No.: US 2017/0307561 A1
(43) Pub. Date: Oct. 26, 2017

(54) INDIUM OXIDE NANOWIRE HAVING COPPER-BASED DOPANTS, METHOD OF FORMING THE SAME AND GAS SENSOR HAVING THE SAME, AND METHOD OF FORMING NANOWIRES HAVING METAL PHTHALOCYANINE, NANOWIRE ARRANGEMENT AND GAS SENSOR HAVING THE SAME

(71) Applicant: Nanyang Technological University, Singapore (SG)

(72) Inventors: Pooi See Lee, Singapore (SG); Chaoyi Yan, Singapore (SG); Jiangxin Wang, Singapore (SG); Nandan Singh, Singapore (SG); Abhishek Singh Dahiya, Singapore (SG)

(21) Appl. No.: 15/523,604

(22) PCT Filed: Nov. 2, 2015
(86) PCT No.: PCT/SG2015/050425

§ 371 Date: May 1, 2017

(30) Foreign Application Priority Data
Oct. 31, 2014 (SG) 10201407136R

(51) Int. Cl. G01N 27/414; C23C 14/08; C01G 15/00

(52) U.S. Cl. CPC G01N 27/4141; C01G 15/00; G01N 27/4146; C23C 14/086; C01P 2002/52; C01P 2002/85; C01P 2004/03; C01P 2004/16; C01P 2004/04

(57) ABSTRACT

According to embodiments of the present invention, a method of forming an indium oxide nanowire including copper-based dopants is provided. The method includes providing an indium-based precursor material and a copper-based dopant precursor material, and performing a thermal evaporation process to vapourise the indium-based precursor material and the copper-based dopant precursor material to form an indium oxide nanowire comprising copper-based dopants on a substrate. According to further embodiments of the present invention, an indium oxide nanowire including copper-based dopants and a gas sensor are also provided. According to further embodiments of the present invention, a method of forming a plurality of nanowires including metal phthalocyanine, a nanowire arrangement and a gas sensor are also provided.

### CROSS-REFERENCE TO RELATED APPLICATION

This application claims the benefit of priority of Singapore patent application No. 10201407136R, filed 31 Oct. 2014, the content of it being hereby incorporated by reference in its entirety for all purposes.

### TECHNICAL FIELD

Various embodiments relate to a method of forming an indium oxide nanowire including copper-based dopants, an indium oxide nanowire including copper-based dopants, a method of forming a plurality of nanowires including metal phthalocyanine, a nanowire arrangement and gas sensors.

### BACKGROUND

Detection and monitoring of atmospheric gases and hazardous molecular species are of critical importance for a wide range of work places, for example, from petrochemical companies, shipyards to wastewater treatment plants, underground car parks and for defence and safety aspects. Gas sensors have an estimated market of USD 1.50 billion in 2012. Existing gas sensors in the market are generally based on bulky technologies with several different operation mechanisms, including electrochemical sensors, catalytic sensors, semiconductor sensors and infrared light sensors. Although the bulky sensors are acceptable for gas sensing in their respective fields, there remains a strong demand for improved sensors, with better performances, lower form factor, and lower costs. As such, there is a need for sensors that are compact, slim, light-weight and handy.

### SUMMARY

According to an embodiment, a method of forming an indium oxide nanowire including copper-based dopants is provided. The method may include providing an indium-based precursor material and a copper-based dopant precursor material, and performing a thermal evaporation process to vapourise the indium-based precursor material and the copper-based dopant precursor material to form an indium oxide nanowire comprising copper-based dopants on a substrate.

According to an embodiment, an indium oxide nanowire including copper-based dopants is provided.

According to an embodiment, a gas sensor is provided. The gas sensor may include at least one indium oxide nanowire including copper-based dopants, and at least one electrode electrically coupled to the at least one indium oxide nanowire.

According to an embodiment, a method of forming a plurality of nanowires including metal phthalocyanine is provided. The method may include providing a solution including a metal phthalocyanine, spin-coating the solution onto a substrate to form a film including the metal phthalocyanine on the substrate, and controlling a heat treatment performed on the film so as to form a plurality of nanowires from the film, the plurality of nanowires comprising the metal phthalocyanine.

According to an embodiment, a nanowire arrangement is provided. The nanowire arrangement may include a substrate, and a film on the substrate, the film including a plurality of metal phthalocyanine nanowires.

According to an embodiment, a gas sensor is provided. The gas sensor may include a film including a plurality of metal phthalocyanine nanowires, and at least one electrode electrically coupled to the plurality of metal phthalocyanine nanowires.

### BRIEF DESCRIPTION OF THE DRAWINGS

In the drawings, like reference characters generally refer to like parts throughout the different views. The drawings are not necessarily to scale, emphasis instead generally being placed upon illustrating the principles of the invention. In the following description, various embodiments of the invention are described with reference to the following drawings, in which:

FIG. 1A shows a flow chart illustrating a method of forming an indium oxide nanowire including copper-based dopants, according to various embodiments.

FIG. 1B shows a schematic cross-sectional view of an indium oxide nanowire including copper-based dopants, according to various embodiments.

FIG. 1C shows a schematic cross-sectional view of a gas sensor, according to various embodiments.

FIG. 1D shows a flow chart illustrating a method of forming a plurality of nanowires including metal phthalocyanine, according to various embodiments.

FIG. 1E shows a schematic perspective view of a nanowire arrangement, according to various embodiments.

FIG. 1F shows a schematic perspective view of a gas sensor, according to various embodiments.

FIG. 2 shows a scanning electron microscope (SEM) image of synthesized indium oxide (In₂O₃) nanowires, according to various embodiments. The scale bar represents 1 μm.

FIG. 3A shows a high-resolution transmission electron microscopy (HRTEM) image of a copper-indium oxide (Cu—In₂O₃) nanowire, according to various embodiments.

FIG. 3B shows a corresponding high-resolution transmission electron microscopy (HRTEM) image of copper-indium oxide (Cu—In₂O₃) nanowires, according to various embodiments, illustrating the lattice spacing.

FIG. 3C shows a corresponding selected area electron diffraction (SAED) pattern recorded along a <211> zone axis of a copper-indium oxide (Cu—In₂O₃) nanowire, according to various embodiments.

FIG. 3D shows an electron backscatter diffraction (EDS) pattern of copper-indium oxide (Cu—In₂O₃) nanowires, according to various embodiments.

FIG. 4A shows a schematic diagram illustrating a device structure of a single nanowire gas sensor, according to various embodiments.

FIG. 4B shows a scanning electron microscope (SEM) image of a single nanowire device with a 4-probe setup, according to various embodiments.

FIG. 5A shows a drain current (I_{d})-time plot for a single copper-indium oxide nanowire field effect transistor (Cu—In₂O₃ NW-FET) when exposed to 5 ppm carbon monoxide (CO) gas in different cycles, according to various embodiments.

FIG. 5B shows a sensor response versus time plot for a single copper-indium oxide nanowire field effect transistor (Cu—In₂O₃ NW-FET) when exposed to 5 ppm carbon monoxide (CO) gas, according to various embodiments.

FIG. 5C shows a plot illustrating a single cycle extracted from the plot of FIG. 5B.

FIG. 5D shows a sensor response versus time plot for an undoped indium oxide nanowire field effect transistor (In₂O₃ NW-FET), when exposed to 5 ppm carbon monoxide (CO) gas, according to various embodiments.

FIG. 6 shows a plot illustrating a current-time relationship for an indium oxide (In₂O₃) nanowire network two-terminal sensor detection of methane (CH₄) gas, according to various embodiments.

FIG. 7A shows a scanning electron microscope (SEM) image at high magnification for copper phthalocyanine (CuPc) on a glass substrate, according to various embodiments. The scale bar represents 1 μm.

FIG. 7B shows a plot illustrating a relationship of sensitivity versus time for nitrogen dioxide (NO₂) sensing for a thick film copper phthalocyanine (CuPc) gas sensor, according to various embodiments.

FIGS. 8A to 8C show plots of sensitivity versus time for a thin film copper phthalocyanine (CuPc) gas sensor when subjected to nitrogen dioxide (NO₂) of about 2 cc/min, about 3 cc/min, and about 4 cc/min respectively, according to various embodiments.

FIG. 9A shows a schematic front view of a portable sensor card, according to various embodiments.

FIG. 9B shows an exploded side view of the portable sensor card of FIG. 9A.

### DETAILED DESCRIPTION

The following detailed description refers to the accompanying drawings that show, by way of illustration, specific details and embodiments in which the invention may be practiced. These embodiments are described in sufficient detail to enable those skilled in the art to practice the invention. Other embodiments may be utilized and structural, logical, and electrical changes may be made without departing from the scope of the invention. The various embodiments are not necessarily mutually exclusive, as some embodiments can be combined with one or more other embodiments to form new embodiments.

Embodiments described in the context of one of the methods or devices are analogously valid for the other methods or devices. Similarly, embodiments described in the context of a method are analogously valid for a device, and vice versa.

Features that are described in the context of an embodiment may correspondingly be applicable to the same or similar features in the other embodiments. Features that are described in the context of an embodiment may correspondingly be applicable to the other embodiments, even if not explicitly described in these other embodiments. Furthermore, additions and/or combinations and/or alternatives as described for a feature in the context of an embodiment may correspondingly be applicable to the same or similar feature in the other embodiments.

In the context of various embodiments, the articles “a”, “an” and “the” as used with regard to a feature or element include a reference to one or more of the features or elements.

In the context of various embodiments, the phrase “at least substantially” may include “exactly” and a reasonable variance.

In the context of various embodiments, the term “about” or “approximately” as applied to a numeric value encompasses the exact value and a reasonable variance.

As used herein, the term “and/or” includes any and all combinations of one or more of the associated listed items.

As used herein, the phrase of the form of “at least one of A or B” may include A or B or both A and B. Correspondingly, the phrase of the form of “at least one of A or B or C”, or including further listed items, may include any and all combinations of one or more of the associated listed items.

Various embodiments provide miniaturization of sensors based on nanowires and granular network.

Various embodiments may provide nanowire gas sensors that are highly sensitive (detection limit<1 ppm), selective (with engineered materials/structures for targeted gases), fast response (achieving<1 s response), with low power consumption (10⁻⁸-10⁻⁶ W) and remarkable stability (intrinsic stability of nanomaterials).

Various embodiments may provide nanowire sensors that may allow efficient shrinking of product sizes, from the existing bulky sensors to a slim sensor card size. Various embodiments may further provide a highly integrated portable nanowire sensor card that is promising for commercialization in view of the broad market needs, with improved performances, enhanced portability, slim and compact design, and lower costs.

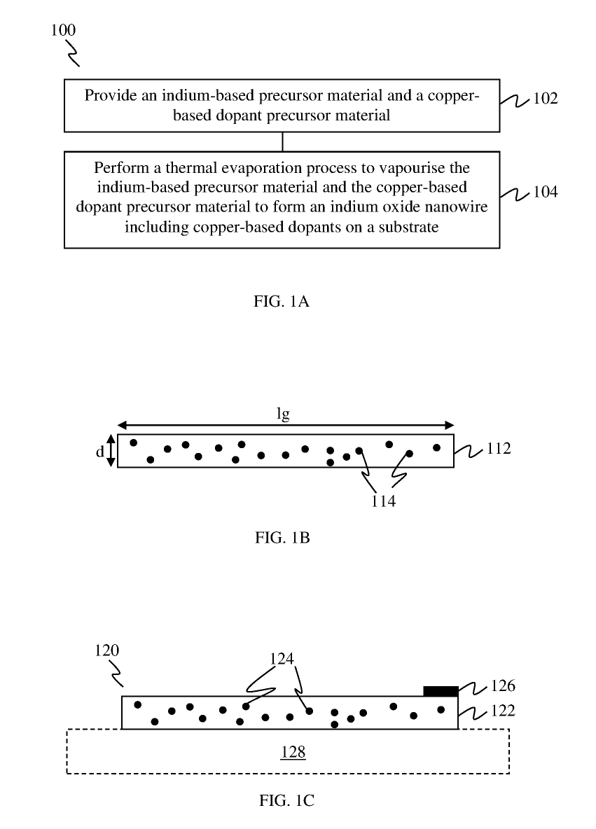

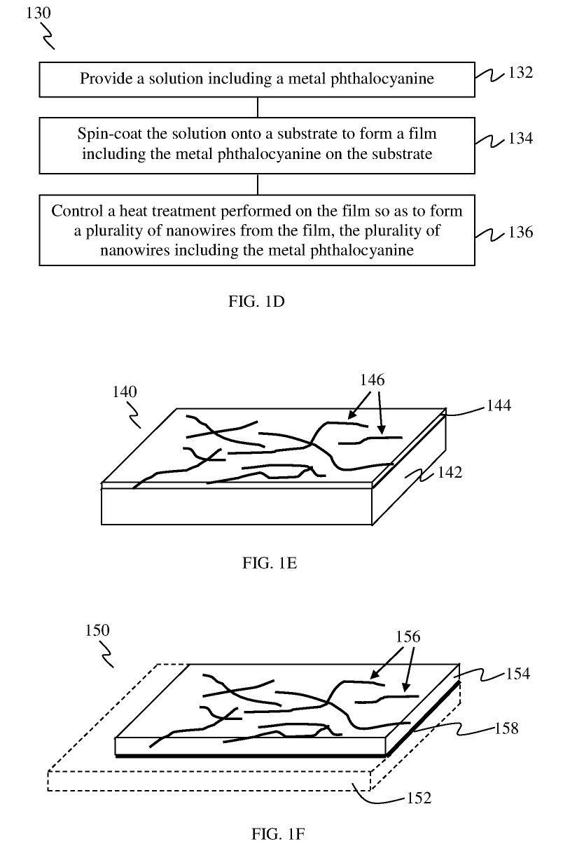

FIG. 1A shows a flow chart 100 illustrating a method of forming an indium oxide (In₂O₃) nanowire including copper (Cu)-based dopants, according to various embodiments.

At 102, an indium (In)-based precursor material and a copper (Cu)-based dopant precursor material are provided.

At 104, a thermal evaporation process is performed to vapourise the indium-based precursor material and the copper-based dopant precursor material to form an indium oxide (In₂O₃) nanowire including copper (Cu)-based dopants on a substrate (e.g., a silicon (Si) substrate). This may mean that the indium oxide nanowire may be doped with copper-based dopants, or in other words, the indium oxide nanowire may be copper-doped.

In various embodiments, at 104, the indium-based precursor material and the copper-based dopant precursor material may be heated to generate respective vapours therefrom, where the respective vapours may be deposited on the substrate to form an indium oxide nanowire including copper-based dopants on the substrate. The respective vapours generated from the indium-based precursor material and the copper-based dopant precursor material may interact or react with each other prior to deposition on the substrate or prior to forming the indium oxide nanowire including the copper-based dopants.

In various embodiments, the indium-based precursor material and the copper-based dopant precursor material may be provided in or into a quartz tube, e.g., towards a sealed end of the quartz tube. A substrate may also be provided in the quartz tube, e.g., towards an open end of the quartz tube. The open end and the sealed end of the quartz tube may be opposite ends. At 104, the thermal evaporation process may be performed in a furnace, for example, a (horizontal) tube furnace. This may mean that the quartz tube having the indium-based precursor material, the copper-based dopant precursor material and the substrate may be positioned in the (tube) furnace.

In the context of various embodiments, the thermal evaporation process may be a vapour deposition process, e.g., a chemical vapour deposition (CVD) process.

In the context of various embodiments, the term “precursor material” may mean a starting material.

In various embodiments, the indium-based precursor material and the copper-based dopant precursor material may be provided at a molar ratio between about 3:1 and about 20:1, for example, between about 3:1 and about 10:1, between about 3:1 and about 5:1, between about 5:1 and about 20:1, or between about 5:1 and about 10:1, e.g., about 10:1. This may mean that the molar ratio of indium-based precursor material: copper-based dopant precursor material may be in a range of about 3:1 to about 20:1

In various embodiments, at 104, the thermal evaporation process may be performed at a (predetermined) temperature between about 700° C. and about 1000° C., for example, between about 700° C. and about 900° C., between about 700° C. and about 800° C., or between about 800° C. and about 1000° C., e.g., about 875° C. As a non-limiting example, the central temperature of the (tube) furnace (or the temperature at the central part of the (tube) furnace, for example, where the indium-based precursor material and the copper-based dopant precursor material may be positioned), may be increased at a ramping rate of about 15° C./min from room temperature (e.g., about 25° C.) to the (predetermined) temperature (e.g., about 875° C.).

In various embodiments, at 104, the thermal evaporation process may be performed for a (predetermined) duration of between about 10 minutes and about 300 minutes, for example, between about 10 minutes and about 200 minutes, between about 10 minutes and about 100 minutes, between about 10 minutes and about 50 minutes, between about 100 minutes and about 300 minutes, or between about 100 minutes and about 200 minutes, e.g., about 60 minutes. This may mean that the (predetermined) temperature may be maintained for the (predetermined) duration.

In various embodiments, at 104, the substrate may be maintained at a (predetermined) temperature between about 400° C. and about 500° C. during the thermal evaporation process, for example, between about 400° C. and about 450° C. or between about 450° C. and about 500° C. As a non-limiting example, while the central temperature of the (tube) furnace (or the temperature at the central part of the (tube) furnace, for example, where the indium-based precursor material and the copper-based dopant precursor material may be positioned), may be at a (predetermined) temperature between about 700° C. and about 1000° C., the substrate may be positioned at a portion of the (tube) furnace where the temperature may be at about 400° C.-500° C.

In various embodiments, at 104, the thermal evaporation process may be performed in an at least substantially vacuum environment. The thermal evaporation process may be performed at a (vacuum) pressure of between about 0.01 mbar and about 5 mbar, for example, between about 0.01 mbar and about 3 mbar, between about 0.01 mbar and about 1 mbar, between about 0.01 mbar and about 0.1 mbar, between about 0.1 mbar and about 5 mbar, between about 1 mbar and about 5 mbar, or between about 0.1 mbar and about 1 mbar. For example, the tube furnace where the thermal evaporation process may be carried out may be sealed and vacuumed to a predetermined (vacuum) pressure, for example, between about 0.01 mbar and about 5 mbar, e.g., a pressure of about 0.01 mbar.

In various embodiments, the method may further include mixing the indium-based precursor material with the copper-based dopant precursor material.

In various embodiments, a carbon-based material may be mixed with the mixture of the indium-based precursor material and the copper-based dopant precursor material. The carbon-based material may be provided at a 1:1 molar ratio with the mixture of the indium-based precursor material and the copper-based dopant precursor material. The carbon-based material may be carbon black. The carbon-based material or the carbon black may be provided to assist in the carbothermal reaction or combustion of the reaction.

In various embodiments, the method may further include introducing an inert gas during the thermal evaporation process. The inert gas may carry or flow the respective vapours corresponding to the indium-based precursor material and the copper-based dopant precursor material resulting from the thermal evaporation process. In this way, the inert gas may act as a carrier gas. In various embodiments, the inert gas may include at least one of argon (Ar) or nitrogen (N₂), optionally with presence of oxygen (O₂) included with the inert gas. For example, while optional, it may be preferable to include O₂ to tailor the stoichiometry of In₂O₃. The introduction of oxygen may reduce oxygen deficient sites in the In₂O₃ nanowires.

In various embodiments, the ratio of the inert gas to oxygen may be in the range of about 100:1 to about 5:1, for example, between about 50:1 and about 5:1, between about 10:1 and about 5:1, between about 100:1 and about 50:1, or between about 50:1 and about 20:1.

In various embodiments, the inert gas (and the oxygen gas) may be introduced at a flow rate of between about 1 sccm and about 1000 sccm, for example, between about 1 sccm and about 500 sccm, between about 1 sccm and about 100 sccm, between about 1 sccm and about 50 sccm, between about 50 sccm and about 1000 sccm, or between about 50 sccm and about 100 sccm, e.g., about 50 sccm.

In the context of various embodiments, the indium-based precursor material may include at least one of indium oxide, indium trichloride(s), indium nitrate(s), indium acetate, indium sulfide, indium sulfate or indium hydroxide(s), for example, an indium oxide (In₂O₃)-based precursor material, e.g., indium oxide (In₂O₃) powder.

In the context of various embodiments, the copper-based dopant precursor material may include at least one of copper oxide, cuprous oxide, cupric oxide, cupric chloride, copper oxychloride, cuprous chloride, cupric nitrate, copper nahpthenate, copper acetate or copper sulphate, for example, copper oxide (CuO) powder.

In various embodiments, the method may further include coating the substrate with a metal. The metal may act as a catalyst for the formation of the indium oxide nanowire including the copper-based dopants. The metal or the catalyst may include at least one of gold (Au) silver (Ag), nickel (Ni), platinum (Pt), palladium (Pd), zinc (Zn), molybdenum (Mo), tin (Sn), manganese (Mn), germanium (Ge), or bismuth (Bi). However, it should be appreciated that other metal or material may be used as the catalyst.

FIG. 1B shows a schematic cross-sectional view of an indium oxide (In₂O₃) nanowire 112 including copper (Cu)-based dopants (shown as solid black circles) 114, according to various embodiments.

In various embodiments, the copper-based dopants 114 may include copper dopant atoms 114. It should be appreciated that in various embodiments, in addition to the copper-based dopants 114 or in the alternative, other dopants such as tin (Sn), iron (Fe), cobalt (Co), magnesium (Mg), aluminum (Al), zinc (Zn), germanium (Ge), bismuth (Bi), lead (Pb), platinum (Pt), palladium (Pd), arsenic (As), selenium (Se), or gallium (Ga), may also be employed.

In various embodiments, a diameter, d, of the indium oxide nanowire 112 may be between about 50 nm and about 300 nm, for example, between about 50 nm and about 150 nm, between about 50 nm and about 100 nm, between about 100 nm and about 150 nm, between about 70 nm and about 120 nm, or between 150 nm and about 300 nm.

In various embodiments, a length, 1 g, of the indium oxide nanowire 112 may be between about 0.5 μm and about 10 μm, for example, between about 0.5 μm and about 5 μm, between about 0.5 μm and about 2 μm, between about 1 μm and about 10 μm, between about 5 μm and about 10 μm, or between about 2 μm and about 5 μm.

FIG. 1C shows a schematic cross-sectional view of a gas sensor 120, according to various embodiments. The gas sensor 120 includes at least one indium oxide (In₂O₃) nanowire 122 including copper (Cu)-based dopants (shown as solid black circles) 124, and at least one electrode 126 electrically coupled to the at least one indium oxide nanowire 122. This may mean that the gas sensor 120 may be a nanowire gas sensor. In various embodiments, the indium oxide nanowire 122 may be as described in the context of the indium oxide nanowire 112.

The at least one electrode 126 may serve as an electrical contact for the at least one indium oxide nanowire 122. The at least one electrode 126 may be provided on or over the at least one indium oxide nanowire 122.

In various embodiments, the at least one indium oxide nanowire 122 including the copper-based dopants 124 may act as a gas sensing element. This may mean that the at least one indium oxide nanowire 122 including the copper-based dopants 124 may be used for sensing gas. As a non-limiting example, at least one parameter (e.g., conductivity or resistivity) of the at least one indium oxide nanowire 122 may change in response to a gas interacting with the at least one indium oxide nanowire 122. The gas may contact the at least one indium oxide nanowire 122. For example, molecules of the gas may be adsorbed in or on the at least one indium oxide nanowire 122.

In various embodiments, the gas sensor 120 may further include a substrate 128 (shown as a dashed box, not in scale relative to the nanowire 122), wherein the at least one indium oxide nanowire 122 may be arranged on the substrate 128. The substrate 128 may include silicon (Si). In various embodiments, the substrate may include or consist of a dielectric (for example, silicon dioxide, oxynitride(s), nitride(s), rare earth oxide(s), or transition metal oxide(s)) deposited on a semiconductor material such as silicon (Si), germanium (Ge), or silicon on insulator (SOI). In various embodiments, for low temperature processes, the substrate 128 may be or may include a polymeric substrate such as polyester, polyethylene terephthalate, polycarbonate, polyimide, or polyether ether ketone.

In various embodiments, the gas sensor 120 may include a single indium oxide nanowire 122 including the copper-based dopants 124.

In various embodiments, the gas sensor 120 may include a plurality of indium oxide nanowires 122, each indium oxide nanowire 122 of the plurality of indium oxide nanowires 122 including the copper-based dopants 124. This may mean that each indium oxide nanowire 122 may be copper-doped. The plurality or array of indium oxide nanowires 122 may define a nanowire network.

In various embodiments, the plurality of indium oxide nanowires 122 may be spaced apart from each other.

In various embodiments, the nanowires 122 may be core-shell nanowires, or nanowires with one or more particulates, or nanowires with one or more chemical coatings.

In various embodiments, adjacent indium oxide nanowires 122 of the plurality of indium oxide nanowires 122 may be in contact with each other. In this way, the adjacent indium oxide nanowires 122 may define an interface, e.g., a nanowire-nanowire interface.

In various embodiments, the plurality of indium oxide nanowires 122 may be at least substantially parallel to each other.

In various embodiments, the gas sensor 120 may include two electrodes (one of which may be electrode 126) electrically coupled to the at least one indium oxide nanowire 122, wherein the two electrodes may be arranged spaced apart from each other. The two electrodes may be provided on opposite ends of the at least one indium oxide nanowire 122. In various embodiments, the two electrodes may, for example, define source and drain electrodes respectively. In this way, the indium oxide nanowire 122 and the two electrodes may define a nanowire transistor based on transistor configuration (e.g., the gas sensor 120 may be a transistor type gas sensor). This may mean that the gas sensor 120 may be a copper-doped indium oxide nanowire transistor (e.g., field effect transistor, FET)-based gas sensor.

In various embodiments, the at least one electrode 126 may include a metal. The at least one electrode may include at least one of titanium (Ti) or gold (Au).

In various embodiments, the gas sensor 120 may further include a display. The display may be a touch display or a touch screen display, meaning that the display (or screen) may be responsive to the touch of a user.

In various embodiments, the gas sensor 120 may further include an audio output means (e.g., for outputting an alarm). For example, an alarm may be provided or activated when an amount of a predetermined gas sensed by the gas sensor 120 exceeds a predetermined threshold level.

In various embodiments, the gas sensor 120 may further include a power source (e.g., a battery such as a lithium battery). The power source may be a rechargeable power source.

In various embodiments, the gas sensor 120 may be a portable gas sensor.

In various embodiments, the gas sensor 120 may be a card-sized gas sensor. This may mean that the gas sensor 120 may be configured or arranged in the form or size of a card (e.g., a credit card).

In the context of various embodiments, the gas sensor 120 may be a resistor type sensor. The resistivity of the at least one indium oxide nanowire 122 may be modulated in response to an interaction of the at least one indium oxide nanowire 122 with a gas which the gas sensor 120 may be exposed to and which may be sensitive to.

In the context of various embodiments, the gas sensor 120 may be employed to sense (or detect) gases including but not limited to methane (CH₄), carbon monoxide (CO), oxygen (O₂), nitrogen dioxide (NO₂), hydrogen sulfide (H₂S), and ammonia (NH₃), and volatile organic compounds (VOCs) including but not limited to isobutylene, perchloroethylene, formaldehyde, benzene, methylene chloride etc.

Various embodiments may also provide a device including at least one indium oxide (In₂O₃) nanowire including copper (Cu)-based dopants, and at least one electrode electrically coupled to the at least one indium oxide nanowire. The elements or components of the device may be as described in the context of the gas sensor 120.

In the context of various embodiments, the term “copper-based dopants” refer to copper-based doping members or copper-based impurities or copper-based doping atoms that may be present. This may mean that the term “copper-based dopants” may include dopants or doping atoms which may be of the same (copper-based) species.

FIG. 1D shows a flow chart 130 illustrating a method of forming a plurality of nanowires including metal phthalocyanine, according to various embodiments.

At 132, a solution including a metal phthalocyanine is provided.

At 134, the solution is spin-coated onto a substrate to form a film including the metal phthalocyanine on the substrate.

At 136, a heat treatment performed on the film may be controlled so as to form a plurality of nanowires from the film, the plurality of nanowires including (or consisting of) the metal phthalocyanine. This may mean performing a heat treatment on the film and controlling the heat treatment, for example, in terms of at least one associated parameter such as temperature and/or duration of the heat treatment, so as to enable formation of the plurality of nanowires including the metal phthalocyanine (or plurality of metal phthalocyanine nanowires).

The plurality of metal phthalocyanine nanowires that may be formed may originate from the film.

The plurality of metal phthalocyanine nanowires may be formed on the substrate. The substrate may be heated, for example, to a predetermined temperature, to form the plurality of metal phthalocyanine nanowires on the substrate.

In various embodiments, at 134, spin-coating the solution onto the substrate may be carried out at room temperature (e.g., 25° C.). Spin-coating the solution onto the substrate may be carried out in air (e.g., ambient atmosphere or environment).

In various embodiments, at 134, the solution may be spin-coated onto the substrate at a (spin) rate or spin speed of between about 100 rpm and about 5000 rpm, for example, between about 100 rpm and about 2500 rpm, between about 100 rpm and about 1000 rpm, between about 2500 rpm and about 5000 rpm, between about 500 rpm and about 2500 rpm, e.g., about 2500 rpm. The term “rpm” means revolutions per minute.

In various embodiments, at 134, the solution may be spin-coated onto the substrate for a duration of between about 5 seconds and about 300 seconds, for example, between about 5 seconds and about 100 seconds, between about 5 seconds and about 30 seconds, between about 30 seconds and about 300 seconds, between about 100 seconds and about 300 seconds, or between about 50 seconds and about 100 seconds, e.g., about 30 seconds.

In various embodiments, at 136, the heat treatment may be performed in air (e.g., ambient atmosphere or environment).

In various embodiments, at 136, controlling a heat treatment performed on the film may include performing the heat treatment at a temperature of between about 50° C. and about 200° C., for example, between about 50° C. and about 150° C., between about 50° C. and about 100° C., or between about 100° C. and about 200° C.

In various embodiments, at 136, controlling a heat treatment performed on the film may include performing the heat treatment for a duration of at least 10 minutes (i.e., ≧10 minutes), for example, ≧20 minutes, ≧30 minutes, ≧40 minutes, ≧50 minutes or ≧60 minutes.

In various embodiments, at 136, controlling a heat treatment performed on the film may include performing the heat treatment at a temperature of about 100° C. for a duration of about 10 minutes. Subsequently, or thereafter, the heat treatment may be further performed at a temperature of about 140° C. for a duration of about 60 minutes. This may mean that the heat treatment may include 2 stages or processes, for example, at a temperature of about 100° C. for a duration of about 10 minutes, and following that, at a temperature of about 140° C. for a duration of about 60 minutes.

In various embodiments, the method may further include stirring the solution. The solution may be stirred at a (stiffing) rate of between about 100 rpm and about 2000 rpm, for example, between about 100 rpm and about 1000 rpm, between about 100 rpm and about 500 rpm, between about 400 rpm and about 2000 rpm, between about 400 rpm and about 1000 rpm, or between about 1000 rpm and about 2000 rpm, e.g., about 400 rpm.

In various embodiments, at 132, a precursor material including the metal phthalocyanine (e.g., a metal phthalocyanine powder) may be dissolved in at least one solvent to provide the solution. The at least one solvent may include (a mixture of) chlorobenzene and trifluoroacetic acid.

In various embodiments, a concentration of the metal phthalocyanine in the solution may be between about 0.01 wt % and about 20 wt %, for example, between about 0.01 wt % and about 10 wt %, between about 0.01 wt % and about 5 wt %, between about 0.01 wt % and about 1 wt %, between about 0.01 wt % and about 0.5 wt %, between about 0.5 wt % and about 20 wt %, between about 1 wt % and about 20 wt %, or between about 0.5 wt % and about 5 wt %, e.g., about 0.5 wt %.

In various embodiments, the method may further include forming at least one electrode on the substrate prior to spin-coating the solution onto the substrate. This may mean that the solution may be spin-coated onto the at least one electrode. In this way, at least part of the film may be formed on the at least one electrode. The at least one electrode may include at least one of titanium (Ti) or gold (Au).

In various embodiments, a metal layer may be formed on the substrate, and the metal layer may be patterned (e.g., by lithography) to form the at least one electrode.

In various embodiments, at 136, controlling the heat treatment performed on the film may include heating the at least one electrode, for example, based on the parameters (e.g., temperature and/or duration) associated with the heat treatment as described above.

In various embodiments, the plurality of nanowires may be comprised in the film.

In various embodiments, a thickness of the film may be between about 50 nm and about 1000 nm, for example between about 50 nm and about 500 nm, between about 50 nm and about 200 nm, between about 200 nm and about 1000 nm, between about 100 nm and about 500 nm, e.g., about 200 nm.

In the context of various embodiments, the substrate may include a polymer substrate or a plastic substrate or a glass substrate. The substrate may be flexible, meaning that the substrate may be made of a flexible material.

In the context of various embodiments, the metal phthalocyanine may include (or consists of) copper phthalocyanine (CuPc). This may mean that each metal phthalocyanine nanowire of the plurality of metal phthalocyanine nanowires may include (or consist of) copper phthalocyanine (CuPc). In the context of various embodiments, other metals such as at least one of nickel (Ni), iron (Fe), zinc (Zn), magnesium (Mg), or cobalt (Co) may also be employed to form the metal phthalocyanine, e.g., nickel phthalocyanine, iron phthalocyanine, zinc phthalocyanine, magnesium phthalocyanine or cobalt phthalocyanine.

FIG. 1E shows a schematic perspective view of a nanowire arrangement 140, according to various embodiments. The nanowire arrangement 140 includes a substrate 142, and a film 144 on the substrate 142, the film 144 including a plurality of metal phthalocyanine nanowires (shown as solid lines) 146. This may mean that the plurality of metal phthalocyanine nanowires 146 may be formed on the substrate 142.

The film 144 may include the metal phthalocyanine of the plurality of metal phthalocyanine nanowires 146.

In various embodiments, the plurality of metal phthalocyanine nanowires 146 may include or consist of the metal phthalocyanine.

In various embodiments, the plurality of metal phthalocyanine nanowires 146 may be interconnected to each other (or intertwined with each other).

In various embodiments, a thickness of the film 144 may be between about 50 nm and about 1000 nm, for example, between about 50 nm and about 500 nm, between about 50 nm and about 200 nm, between about 200 nm and about 1000 nm, or between about 50 nm and about 500 nm, e.g., about 200 nm.

In various embodiments, the film 144 may be spin-coated on the substrate 142, meaning a spin-coated film.

In the context of various embodiments, the substrate 142 may include a polymer substrate or a plastic substrate or a glass substrate. The substrate may be flexible, meaning that the substrate may be made of a flexible material.

In the context of various embodiments, the plurality of metal phthalocyanine nanowires 146 may include (or consist of) copper phthalocyanine (CuPc). This may mean that each metal phthalocyanine nanowire 146 of the plurality of metal phthalocyanine nanowires 146 may include (or consist of) copper phthalocyanine (CuPc). In the context of various embodiments, other metals such as at least one of nickel (Ni), iron (Fe), zinc (Zn), magnesium (Mg), or cobalt (Co) may also be employed to form the plurality of metal phthalocyanine nanowires 146, e.g., each metal phthalocyanine nanowire 146 may include (or consist of) nickel phthalocyanine, iron phthalocyanine, zinc phthalocyanine, magnesium phthalocyanine or cobalt phthalocyanine.

In the context of various embodiments, an aspect ratio of each metal phthalocyanine nanowire 146 of the plurality of metal phthalocyanine nanowires 146 may be between about 5 and about 100, for example, between about 5 and about 50, between about 5 and about 20, between about 5 and about 10, between about 20 and about 100, between about 10 and about 50.

In the context of various embodiments, a diameter of each metal phthalocyanine nanowire 146 of the plurality of metal phthalocyanine nanowires 146 may be between about 50 nm and about 150 nm, for example, between about 50 nm and about 100 nm, between about 100 nm and about 150 nm, or between about 70 nm and about 120 nm.

In the context of various embodiments, a length of each metal phthalocyanine nanowire 146 of the plurality of metal phthalocyanine nanowires 146 may be between about 50 nm (0.05 μm) and about 20 μm, for example, between about 50 nm and about 10 μm, between about 50 nm and about 5 μm, between about 50 nm and about 1 μm, between about 1 μm and about 20 μm, between about 1 μm and about 10 μm, or between about 10 μm and about 20 μm.

FIG. 1F shows a schematic perspective view of a gas sensor 150, according to various embodiments. The gas sensor 150 includes a film 154 including a plurality of metal phthalocyanine nanowires 156, and at least one electrode 158 electrically coupled to the plurality of metal phthalocyanine nanowires 156.

In other words, a gas sensor 150 may be provided, having a film 154 with a plurality of metal phthalocyanine nanowires 156 comprised in the film 154. This may mean that the gas sensor 150 may be a nanowire gas sensor. The plurality of metal phthalocyanine nanowires 156 may include or consist of the metal phthalocyanine. The plurality of metal phthalocyanine nanowires 156 may form a metal phthalocyanine nanowire network. The film 154 may include the metal phthalocyanine of the plurality of metal phthalocyanine nanowires 156. In various embodiments, the plurality of metal phthalocyanine nanowires 156 may be as described in the context of the plurality of metal phthalocyanine nanowires 146.

The gas sensor 150 may further include at least one electrode 158 electrically coupled to the plurality of metal phthalocyanine nanowires 156. The at least one electrode 158 may serve as an electrical contact for the plurality of metal phthalocyanine nanowires 156. The at least one electrode 158 may be provided below the plurality of metal phthalocyanine nanowires 156. The at least one electrode 158 may be electrically coupled to the film 154.

In various embodiments, the plurality of metal phthalocyanine nanowires 156 may act as gas sensing elements. This may mean that the plurality of metal phthalocyanine nanowires 156 may be used for sensing gas. As a non-limiting example, at least one parameter (e.g., conductivity or resistivity) of the plurality of metal phthalocyanine nanowires 156 or of each metal phthalocyanine nanowire 156 may change in response to a gas interacting with the plurality of metal phthalocyanine nanowires 156. The gas may contact the plurality of metal phthalocyanine nanowires 156. For example, molecules of the gas may be adsorbed in or on the plurality of metal phthalocyanine nanowires 156.

The gas sensor 150 may include a substrate 152 (shown as a dashed box, not in scale relative to the film 154), the film 154 being formed on the substrate. The plurality of metal phthalocyanine nanowires 156 may be formed or arranged on the substrate 152.

In various embodiments, the film 154 may be spin-coated on the substrate 152, meaning a spin-coated film.

In the context of various embodiments, the substrate 152 may include a polymer substrate or a plastic substrate or a glass substrate. The substrate may be flexible, meaning that the substrate may be made of a flexible material.

In various embodiments, a thickness of the film 154 may be between about 20 nm and about 1000 nm, for example between about 20 nm and about 500 nm, between about 20 nm and about 200 nm, between about 200 nm and about 1000 nm, between about 100 nm and about 500 nm, or between about 50 nm and about 500 nm, e.g., about 200 nm.

In various embodiments, the plurality of metal phthalocyanine nanowires 156 may be interconnected to each other (or intertwined with each other).

In the context of various embodiments, an aspect ratio of each metal phthalocyanine nanowire 156 of the plurality of metal phthalocyanine nanowires 156 may be between about 5 and about 100, for example, between about 5 and about 50, between about 5 and about 20, between about 5 and about 10, between about 20 and about 100, between about 10 and about 50.

In the context of various embodiments, a diameter of each metal phthalocyanine nanowire 156 of the plurality of metal phthalocyanine nanowires 156 may be between about 50 nm and about 150 nm, for example, between about 50 nm and about 100 nm, between about 100 nm and about 150 nm, or between about 70 nm and about 120 nm.

In the context of various embodiments, a length of each metal phthalocyanine nanowire 156 of the plurality of metal phthalocyanine nanowires 156 may be between about 50 nm (0.05 μm) and about 20 μm, for example, between about 50 nm and about 10 μm, between about 50 nm and about 5 μm, between about 50 nm and about 1 μm, between about 1 μm and about 20 μm, between about 1 μm and about 10 μm, or between about 10 μm and about 20 μm.

In the context of various embodiments, the plurality of metal phthalocyanine nanowires 156 may include (or consist of) copper phthalocyanine (CuPc). This may mean that each metal phthalocyanine nanowire 156 of the plurality of metal phthalocyanine nanowires 156 may include (or consist of) copper phthalocyanine (CuPc). In the context of various embodiments, other metals such as at least one of nickel (Ni), iron (Fe), zinc (Zn), magnesium (Mg), or cobalt (Co) may also be employed to form the plurality of metal phthalocyanine nanowires 156, e.g., each metal phthalocyanine nanowire 156 may include (or consist of) nickel phthalocyanine, iron phthalocyanine, zinc phthalocyanine, magnesium phthalocyanine or cobalt phthalocyanine.

In various embodiments, the at least one electrode 158 may include a metal. The at least one electrode may include at least one of titanium (Ti) or gold (Au).

In various embodiments, the gas sensor 150 may further include a display. The display may be a touch display or a touch screen display, meaning that the display (or screen) may be responsive to the touch of a user.

In various embodiments, the gas sensor 150 may further include an audio output means (e.g., for outputting an alarm). For example, an alarm may be provided or activated when an amount of a predetermined gas sensed by the gas sensor 150 exceeds a predetermined threshold level.

In various embodiments, the gas sensor 150 may further include a power source (e.g., a battery such as a lithium battery). The power source may be a rechargeable power source.

In various embodiments, the gas sensor 150 may be a portable gas sensor.

In various embodiments, the gas sensor 150 may be a card-sized gas sensor. This may mean that the gas sensor 150 may be configured or arranged in the form or size of a card (e.g., a credit card).

In the context of various embodiments, the gas sensor 150 may be a resistor type sensor. The resistivity of the plurality of metal phthalocyanine nanowires 156 or of each metal phthalocyanine nanowire 156 may be modulated in response to an interaction of the plurality of metal phthalocyanine nanowires 156 with a gas which the gas sensor 150 may be exposed to and which may be sensitive to.

In the context of various embodiments, the gas sensor 150 may be employed to sense (or detect) gases including but not limited to methane (CH₄), carbon monoxide (CO), oxygen (O₂), nitrogen dioxide (NO₂), hydrogen sulfide (H₂S), and ammonia (NH₃), and volatile organic compounds (VOCs) including but not limited to isobutylene.

Various embodiments may also provide a device having a film including a plurality of metal phthalocyanine nanowires, and at least one electrode electrically coupled to the plurality of metal phthalocyanine nanowires. The elements or components of the device may be as described in the context of the gas sensor 150.

In the context of various embodiments, the term “nanowire” may mean a nanostructure extending, for example, in a longitudinal direction, with at least one dimension in the order of nanometers, and may be used interchangeably with the terms “nanorod”, “nanopillar”, “nanocolumn”, “nanotube” and the likes.

While the methods described above are illustrated and described as a series of steps or events, it will be appreciated that any ordering of such steps or events are not to be interpreted in a limiting sense. For example, some steps may occur in different orders and/or concurently with other steps or events apart from those illustrated and/or described herein. In addition, not all illustrated steps may be required to implement one or more aspects or embodiments described herein. Also, one or more of the steps depicted herein may be carried out in one or more separate acts and/or phases.

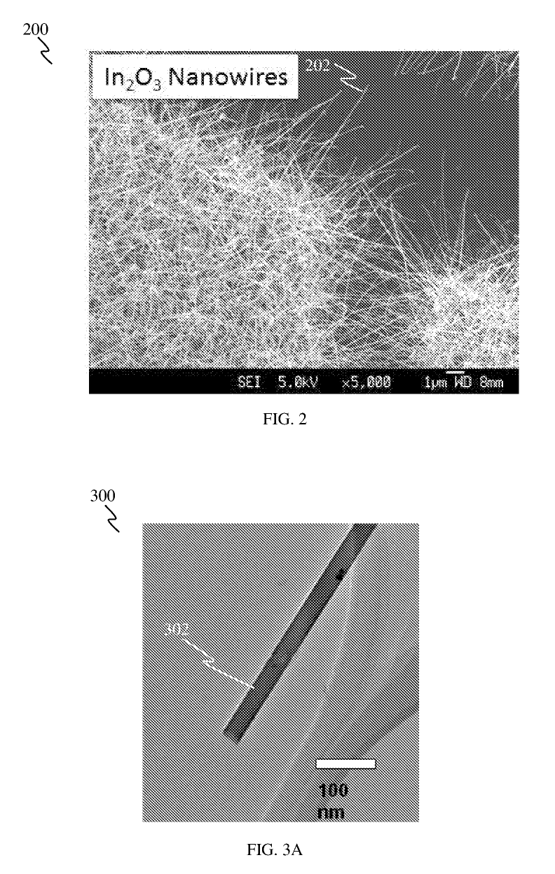

There may be several target gases (CH₄, CO, O₂, H₂S, with >80% share of gas sensor market) or NH₃, and other toxic and hazardous species, volatile organic compounds (VOCs) such as isobutylene that may be of key interests. The microscale sensors in accordance with various embodiments may be based on nanowires as the sensing elements. A scanning electron microscope (SEM) image 200 of synthesized indium oxide (In₂O₃) nanowires 202 is shown in FIG. 2. Tin oxide (SnO₂) nanowires may also be synthesized, which may look similar to the In₂O₃ nanowires 202. The growth conditions may be controlled to obtain nanowires (e.g., In₂O₃ nanowires 202) with significantly uniform structures. The diameters may be in the range of about 50-150 nm and the lengths may be within the range of tens of micrometers. The morphology, structures and crystal phases may be characterized by a series of detailed analysis (not shown here).

Doping of nanowires may play an important role in sensing performance For example, copper-indium oxide (Cu—In₂O₃) nanowires (NWs) may display enhanced sensor response with improved response and recovery time compared to undoped In₂O₃ nanowires-field effect transistors (NW-FETs) for carbon monoxide (CO) sensing operated at room temperature.

Doping in metal oxide NW may cause defects such as oxygen vacancies, metal interstitials, surface defects, etc. These defects may act as preferential adsorption sites for gas molecules and thus may play a vital role in the sensing of gas (e.g., CO gas) at room temperature by enhancing adsorption. Enhanced adsorptions of gas molecules may change the electrical conductivity and hence the position of a Fermi level in the band gap of oxide semiconductors. The modulation of Schottky barrier height (SBH) after the exposure of testing gas molecules may equally contribute to the electrical response of nano-sensors. For example, the higher the SBH changes after the exposure, the faster the sensor response may be.

In various embodiments, the copper-doped indium oxide (Cu doped In₂O₃) nanowires may be synthesized via the following method:—
(I). Indium oxide (In₂O₃) and copper oxide (CuO) powders may be thoroughly mixed at a 10:1 molar ratio. The molar ratio may be varied within 3:1 to 20:1.
(II). The In₂O₃/CuO powders may be mixed with carbon black at a 1:1 molar ratio. The molar ratio of carbon black may be higher than 50% and there may be no upper limit.
(III). The resulting powder (weight of about 1 g) may be loaded into a sealed end of a small quartz tube (diameter of about 15 mm, length of about 30 mm)
(IV). Silicon (Si) substrates coated with gold (Au) catalysts (thickness of the gold catalyst layer is about 5 nm) may be cut into 10 mm by 15 mm sizes and may be loaded into an open end of the small quartz tube.
(V). The small quartz tube may be placed into a horizontal tube furnace.
(VI). The tube furnace may be sealed and vacuumed to a base pressure of about 0.01 mbar.
(VII). High purity argon (Ar) gas may be introduced at a flow rate of about 50 sccm corresponding to a pressure of about 0.57 mbar.
(VIII). A central temperature of the tube furnace may be increased from room temperature (about 25° C.) to about 875° C. at a ramping rate of about 15° C./min. The central temperature may be set in a range of about 700-1000° C.
(IX). The temperature may be held at about 875° C. for about 60 min before cooling to room temperature naturally. The growth time may vary within 10-300 min.
(X). The Si substrates may be located in a temperature region of about 400-500° C. during growth.
(XI). Nanowire products may be collected on the Si substrates after growth.

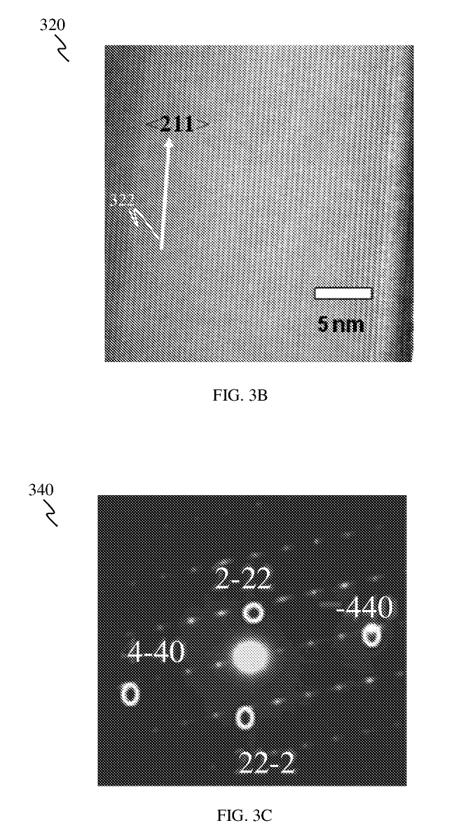

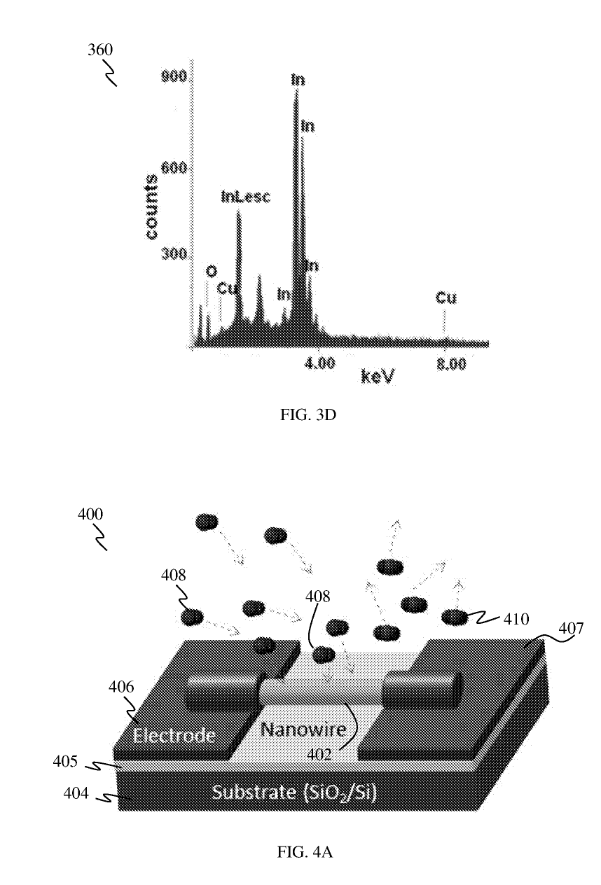

FIG. 3A shows a high-resolution transmission electron microscopy (HRTEM) image 300 of a Cu—In₂O₃ nanowire 302 with a diameter of about 30 nm. FIG. 3B shows a corresponding HRTEM image 320 of Cu—In₂O₃ nanowires with a lattice spacing of about 0.412 nm and FIG. 3C shows a corresponding selected area electron diffraction (SAED) pattern 340 recorded along the <211> zone axis, as indicated by the directional arrow 322 of FIG. 3B. The numerical indications of 4-40, 2-22, -440, 22-2 in FIG. 3C refer to the Miller indices of the crystallography lattice planes in the Bravais lattice. FIG. 3D shows an electron backscatter diffraction (EDS) pattern 360 of the Cu—In₂O₃ nanowires.

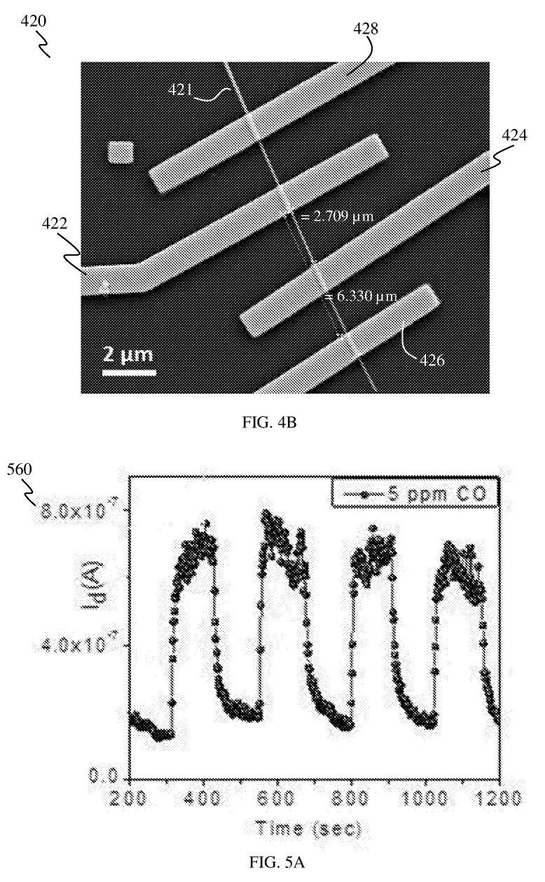

The nanowires may be configured in a device having a network of nanowires based on resistive modulation or a single nanowire transistor based on transistor configuration (for example, as shown in FIG. 4A). As a non-limiting example, a drop of nanowire (NW) suspension (about 2 μl) may be placed between the source-drain of a selected device and an alternating current (AC) field may be applied across the electrodes. The divergent field that is produced by applying an optimized AC voltage of about 6 V and about 400 KHz of frequency between the source-drain electrodes may interact with the finite dipole moment induced in the NW. This may result in a net downward force which may force the NW to be aligned between the two electrodes. After drying, the location of the NW on the electrode may be identified using SEM images of the NW-FETs.

FIG. 4A shows a schematic diagram illustrating a device structure of an exemplary single nanowire gas sensor 400. A nanowire (e.g., the Cu-doped In₂O₃ nanowire as described above) 402 (typically with a diameter about 100 nm and a length of tens of micrometers) may be placed on top of a substrate (e.g., a silicon (Si) wafer 404 coated with an insulating silicon oxide (SiO₂) layer 405). Metal electrodes 406, 407 (e.g., titanium/gold; Ti/Au) may be deposited onto the nanowire 402 as contacts. For example, one of the electrodes 406, 407 may be configured as a source electrode while the other may be configured as a drain electrode. The nanowire device 400 may be, for example, a single copper-indium oxide nanowire field effect transistor (Cu—In₂O₃ NW-FET).

When the nanowire device 400 is exposed to a certain gas, e.g., carbon monoxide (CO) 408, the gas molecules 408 contacting the nanowire surface may exchange electrons with the nanowire 402, that is, undergoing chemical reactions (e.g., oxidation of CO 408 to CO₂ 410), and thus the current levels in the device 400 may change. Consequently, the presence of certain gases may be reflected on the external monitoring system via current differences.

FIG. 4B shows a SEM image 420 of a single nanowire device having a single nanowire 421 with a 4-probe setup having probes 422, 424, 426, 428, as a further example of a device that may be provided. As seen in FIG, 4B, a spacing between the probe 422 and the adjacent probe 424 may be of a distance of about 2.709 μm, while a spacing between the probe 422 and the probe 426 may be of a distance of about 6.330 μm.

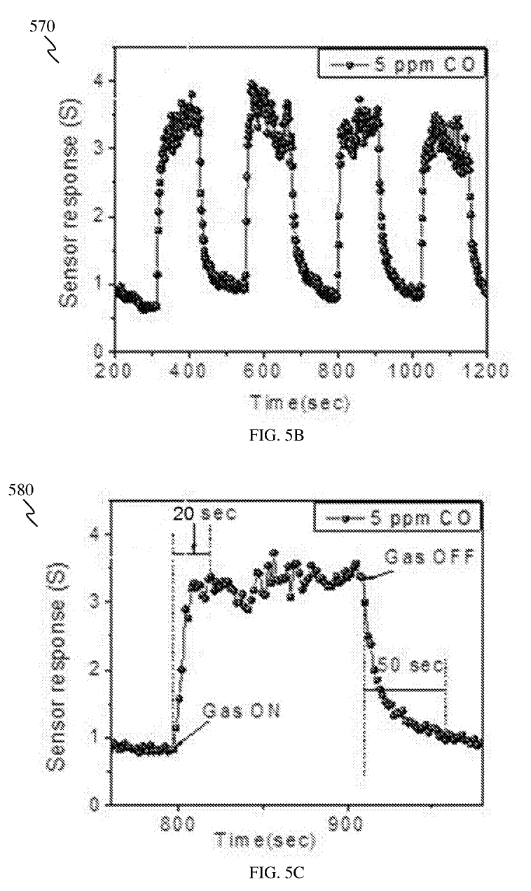

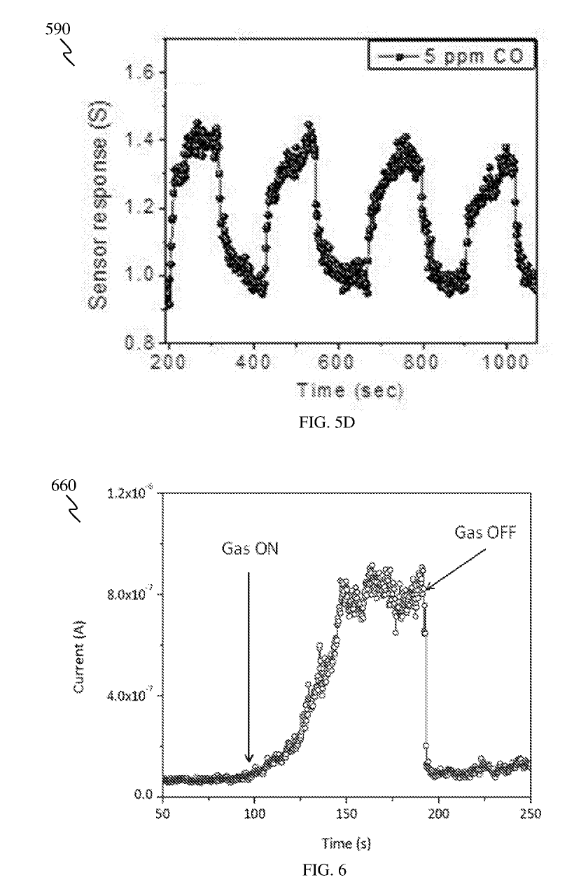

FIGS. 5A to 5D show various gas testing plots 560, 570, 580, 590 for a sensor (e.g., a single Cu—In₂O₃ NW-FET based on the nanowire device 400 of FIG. 4A) operated at room temperature. More specifically, FIG. 5A shows a Id-time plot 560 for a single Cu—In₂O₃ NW-FET when exposed to 5 ppm CO gas in different cycles, where the parameter Id represents the drain current of the NW-FET. FIG. 5B shows a sensor response versus time plot 570 of the same device/sensor when exposed to 5 ppm CO gas, while FIG. 5C shows a plot 580 illustrating a single cycle extracted from the plot 570 of FIG. 5B, showing a response time of about 20 sec (starting from a point when the gas is ON) and a recovery time of about 50 sec (starting from a point when the gas is OFF). FIG. 5D shows a sensor response versus time plot 590 for an undoped In₂O₃ NW-FET, when exposed to 5 ppm CO gas, whose results show a lower sensor response compared to the results (FIG. 5B) obtained for the Cu—In₂O₃ NW-FET.

Sensitivity may be the lower limit of the gas concentrations that a sensor may detect. A high sensitivity may be required to monitor the contents of hazardous gases and alert the users. However, existing gas sensors may not detect gas concentrations down to few ppm levels, due to an intrinsic limit of bulk technologies. For example, the detection limit of CO gas may be as high as 30 ppm (TGS2442, Figaro Engineering Inc., Japan). A typical response behaviour of commercial CO sensor response and reset time may be about 200 seconds and about 600 seconds, respectively. In contrast, the CO gas sensor based on nanowires, in accordance with various embodiments, may show a significantly faster responsive behavior, with response/reset time of about 20/50 seconds, respectively.

The In₂O₃ nanowire network device of various embodiments may be used for two-terminal sensors detection of methane (CH₄) gas, which may exhibit a significantly fast response and reset time as shown in the plot 660 of FIG. 6 as resistor type sensors.

The underlying mechanism may be that conductance of the nanowire network device may be determined by the nanowire-nanowire interface. The intrinsic depletion layer on the nanowire surface may construct Schottky barrier-like conduction barriers in the network. The barrier may be rapidly modulated when exposed to gases, thus leading to a fast responsive behavior. The mechanism may be readily adopted to achieve fast response in other nanowire network gas sensors.

Testing conditions and the results obtained may be as shown in Table I.

TABLE I

| Parameter | Results | |
|---|---|---|
| CH4 content: | 2.5 | vol % |
| Flow rate: | 5 | sccm |
| Temperature: | 25° | C. |
| Response time: | 47 | s |
| Reset time: | 0.8 | s |

| | |
|---|---|
| Sensor response: | 14.3 |

The CH₄ concentration may be about 2.5 vol %. Testing may be performed at room temperature of about 25° C. and no heating may be required. The In₂O₃ nanowires may respond to the CH₄ gas with a response time of about 47 s and a reset time of about 0.8 s. Industrial testing is typically done using combustion wire (platinum (Pt) wire) to catalytically burn the CH₄ at a high temperature and hence enable efficient detection. The testing using the device/sensor of various embodiments may be performed at room temperature in air. That is, the sensors may be exposed in air before introducing the CH₄ gas. The current change may be induced by the change of oxygen environment instead of any reactions with CH₄, since CH₄ is rather inert at room temperature.

In various embodiments, methods to tune the sensitivity and selectivity may include the doping of nanowires, surface functionalization, alloying of nanowires and nanoparticles decorations onto the nanowires or core-shell nanostructures.

Various embodiments may provide a polymer nanowire network, e.g., phthalocyanine (e.g., copper phthalocyanine; CuPc), polypyrrole and polyaniline, which may also be used to establish gas sensing performance

Instead of using the complex evaporation setup or the vapor phase deposition process to form CuPc, which may require a high temperature up to 500° C. or above, an exemplary spin coating method, as explained below, may be used in various embodiments:—
(i) Copper Phthalocyanine (CuPc) powder may be dissolved in chlorobenzene and trifluoroacetic acid to obtain a solution of about 0.5 wt %.
(ii) The solution may be stirred overnight at about 400 rpm. The stiffing speed may vary within 100-2000 rpm.
(iii) The resulting greenish blue solution may be spun coated at about 2500 rpm for about 30 s onto patterned gold (Au) electrodes.
(iv) The electrodes may be heated at about 100° C. for about 10 min and then at about 140° C. for about 60 min The heating temperature may vary within a range of about 50-200° C. and the heating time should be 10 min and more.
(v) CuPc nanowire devices may be obtained after the heat treatment. This method may not require any high temperature steps and may be used for plastic or flexible substrates.

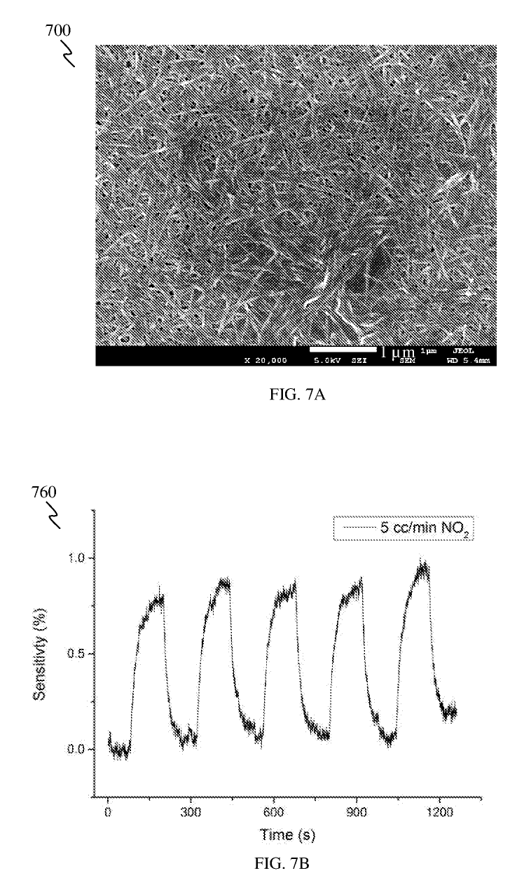

FIG. 7A shows a SEM image 700 at high magnification for CuPc on a glass substrate, depicting a polymer nanowire network of CuPc (Copper Phthalocyanine) 0.5 wt % CuPc may be deposited on the glass substrate and spin-coated at about 2500 rpm and subsequently, annealed at about 140° C. for about 2 hours.

FIG. 7B shows a plot 760 illustrating the relationship of sensitivity versus time for nitrogen dioxide (NO₂) sensing for a thick film (˜700 nm) CuPc gas sensor when subjected to NO₂ of about 2.5 ppm (about 5 cc/min) The sensor (device) may be made with 2 wt % CuPc solution and unannealed. As seen in FIG. 7B, the stability of the nanowire film may be good across 5 cycles of testing at a higher NO₂ concentration of 2.5 ppm, where significantly little change in sensitivity or even degradation may be observed. The response and recovery time of the device may be about 120 s for different NO₂ concentrations, which is faster as compared to the results of 10 mins to 50 mins for an existing device.

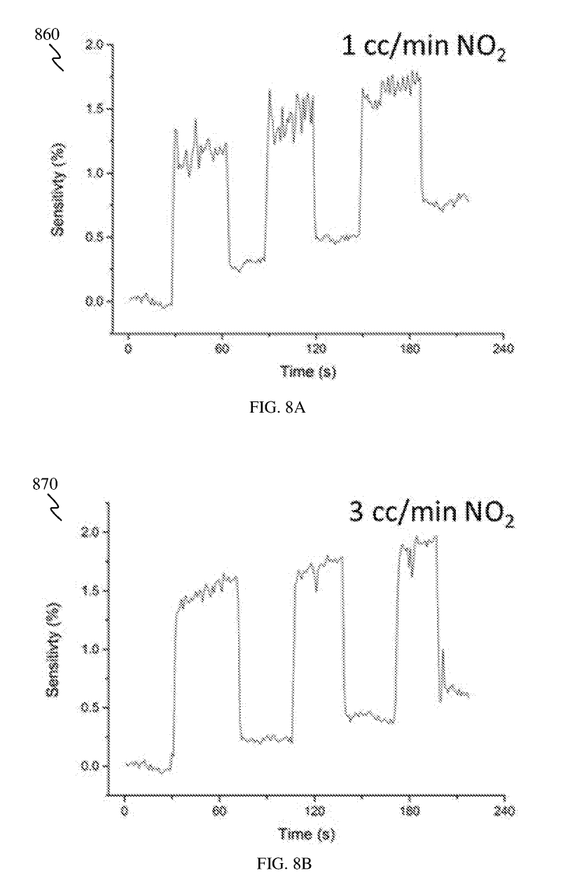

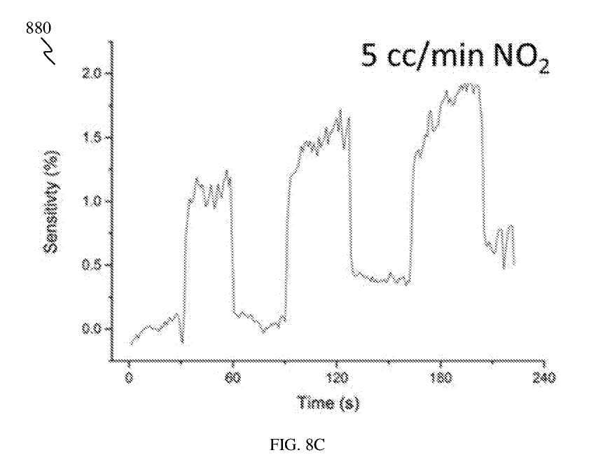

Compared to the thick film CuPc device, a thin film 200 nm device may show a higher sensitivity. However,no significant improvement to the change in conductivity with increasing concentration of NO₂ gas may be observed, as shown in the sensitivity versus time plots 860, 870, 880 of FIGS. 8A to 8C for NO₂ sensing using the thin CuPc gas sensor device of about 200 nm. The thin CuPc gas sensor device may be made with 0.5 wt % CuPc solution and unannealed. More specifically, FIG. 8A shows the sensitivity versus time plot 860 for the thin film (˜200 nm) CuPc gas sensor when subjected to NO₂ of about 0.833 ppm (about 1 cc/min), while FIG. 8B shows the sensitivity versus time plot 870 for the same sensor when subjected to NO₂ of about 1.875 ppm (about 3 cc/min), and FIG. 8C shows the sensitivity versus time plot 880 for the same sensor when subjected to NO₂ of about 2.5 ppm (about 5 cc/min).

The response and the recovery time of the thin film device may be significantly faster than those of the thick film device at about 5 s. This may be due to a higher number of defects found on the thin film of the device, where the thin film may be lesser condensed (e.g., as compared to the thick film device). Therefore, any addition of charge carrier may contribute to a larger change in conductivity as compared to a thicker film with already a better conductivity.

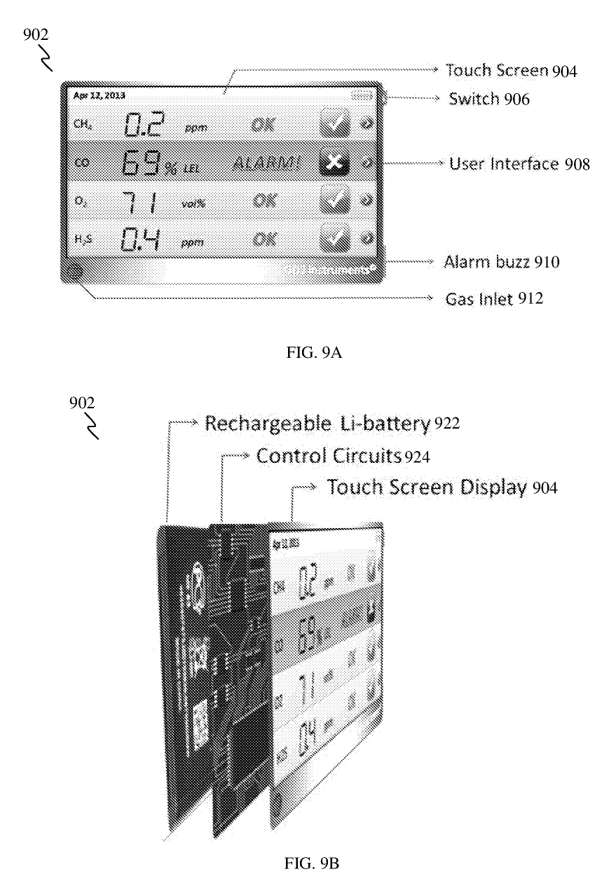

Based on the successful fabrication and testing of key sensing component, the components may be integrated with other functional components into a portable sensor card. FIG. 9A shows a schematic front view of a portable sensor card (e.g., a nanowire gas sensor card) 902 in accordance with various embodiments, and FIG. 9B shows an exploded side view of the portable sensor card 902 of FIG. 9A. As seen in FIG. 9B, functional components of the portable sensor card 902 may include power sources (e.g., a thin rechargable Li-ion battery) 922, control circuits 924, and a light emitting diode (LED) display (e.g., touch screen display 904). The portable sensor card 902 may also include a switch 906, a user interface 908, an alarm buzz 910, and a gas inlet 912, as seen in FIG. 9A. The fabrications of the functional components (except the nanowire sensor) may be readily achievable based on existing technologies within the respective industries.

While the invention has been particularly shown and described with reference to specific embodiments, it should be understood by those skilled in the art that various changes in form and detail may be made therein without departing from the spirit and scope of the invention as defined by the appended claims. The scope of the invention is thus indicated by the appended claims and all changes which come within the meaning and range of equivalency of the claims are therefore intended to be embraced.

1. A method of forming an indium oxide nanowire comprising copper-based dopants, the method comprising:
providing an indium-based precursor material and a copper-based dopant precursor material; and
performing a thermal evaporation process to vapourise the indium-based precursor material and the copper-based dopant precursor material to form an indium oxide nanowire comprising copper-based dopants on a substrate.

2. The method as claimed in claim 1, wherein the indium-based precursor material and the copper-based dopant precursor material are provided at a molar ratio between 3:1 and 20:1.

3. The method as claimed in claim 1, wherein the thermal evaporation process is performed at a temperature between 700° C. and 1000° C.

4. The method as claimed in claim 1, wherein the thermal evaporation process is performed for a duration of between 10 minutes and 300 minutes.

5. The method as claimed in claim 1, further comprising maintaining the substrate at a temperature between 400° C. and 500° C. during the thermal evaporation process.

6. The method as claimed in claim 1, wherein the thermal evaporation process is performed in an at least substantially vacuum environment.

7. (canceled)

8. The method as claimed in claim 1, further comprising mixing the indium-based precursor material with the copper-based dopant precursor material.

9. (canceled)

10. The method as claimed in claim 1, further comprising introducing an inert gas during the thermal evaporation process.

11. (canceled)

12. The method as claimed in claim 1, wherein the indium-based precursor material comprises at least one of indium oxide, indium trichloride, indium nitrate, indium acetate, indium sulfide, indium sulfate or indium hydroxide.

13. (canceled)

14. The method as claimed in claim 1, wherein the copper-based dopant precursor material comprises at least one of copper oxide, cuprous oxide, cupric oxide, cupric chloride, copper oxychloride, cuprous chloride, cupric nitrate, copper nahpthenate, copper acetate or copper sulphate.

15-16. (canceled)

17. An indium oxide nanowire comprising copper-based dopants.

18. The indium oxide nanowire as claimed in claim 17, wherein the copper-based dopants are copper dopant atoms.

19. The indium oxide nanowire as claimed in claim 17, wherein a diameter of the indium oxide nanowire is between 50 nm and 300 nm.

20. The indium oxide nanowire as claimed in claim 17, wherein a length of the indium oxide nanowire is between 0.5 μm and 10 μm.

21. A gas sensor comprising:
at least one indium oxide nanowire comprising copper-based dopants; and
at least one electrode electrically coupled to the at least one indium oxide nanowire.

22. The gas sensor as claimed in claim 21, further comprising a substrate, wherein the at least one indium oxide nanowire is arranged on the substrate.

23. The gas sensor as claimed in claim 21, wherein the gas sensor comprises a single indium oxide nanowire comprising the copper-based dopants.

24. The gas sensor as claimed in claim 21, wherein the gas sensor comprises a plurality of indium oxide nanowires, each indium oxide nanowire of the plurality of indium oxide nanowires comprising the copper-based dopants.

25-28. (canceled)

29. The gas sensor as claimed in claim 21, wherein the at least one electrode comprises a metal.

30-34. (canceled)

35. The gas sensor as claimed in claim 21, wherein the gas sensor is a card-sized gas sensor.

36-86. (canceled)
